(19) United States
(12) Patent Application Publication
(10) Pub. No.: US 2026/0136628 A1
(43) Pub. Date: May 14, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Yung-Ting CHANG, New Taipei (TW); Jui-Lin CHEN, Taipei (TW); Lien-Jung HUNG, Taipei (TW)

(21) Appl. No.: 19/079,735

(22) Filed: Mar. 14, 2025

Related U.S. Application Data
(60) Provisional application No. 63/719,156, filed on Nov. 12, 2024.

(51) Int. Cl. H10D 64/23; H10D 64/01; H10D 84/83

(52) U.S. Cl. CPC H10D 64/254; H10D 64/01; H10D 84/832

(57) ABSTRACT

Embodiments of the present disclosure provide semiconductor device structures and methods of forming the same. The semiconductor device structure includes a first source/drain region, a second source/drain region disposed adjacent the first source/drain region, a contact etch stop layer disposed over the first source/drain region, a first interlayer dielectric (ILD) layer disposed over the contact etch stop layer, an etch stop layer disposed over a top surface of the contact etch stop layer and a top surface of the first ILD layer, a second ILD layer disposed over the etch stop layer, a first conductive feature disposed below the first and second source/drain regions, and a second conductive feature disposed above the first and second source/drain regions. The second conductive feature is electrically connected to the first and second source/drain regions, and the first and second conductive features are in contact with each other.

### CROSS-REFERENCE TO RELATED APPLICATIONS

This application claims priority to U.S. Provisional Application Ser. No. 63/719,156 filed on Nov. 12, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, 9, 10, 11, 12, and 13 are perspective views of various stages of manufacturing a semiconductor device structure, in accordance with some embodiments.

FIGS. 14A and 15A are cross-sectional side views of the semiconductor device structure taken along the line A-A of FIG. 13, in accordance with some embodiments.

FIGS. 14B and 15B are cross-sectional side views of the semiconductor device structure taken along the line B-B of FIG. 13, in accordance with some embodiments.

FIGS. 14C and 15C are cross-sectional side views of the semiconductor device structure taken along the line C-C of FIG. 13, in accordance with some embodiments.

FIGS. 16, 17, 18, 19, 20, and 21 are cross-sectional side views of the semiconductor device structure at various manufacturing stages, in accordance with some embodiments.

FIGS. 22 and 23 are cross-sectional side views of the semiconductor device structure at one of various manufacturing stages, in accordance with alternative embodiments.

FIG. 24 is a top view of the semiconductor device structure, in accordance with some embodiments.

FIG. 25 is a cross-sectional side view of the semiconductor device structure taken along the line D-D of FIG. 24, in accordance with some embodiments.

FIG. 26 is a circuit diagram of two 7T SRAM cells, in accordance with some embodiments.

FIG. 27 is a top view of the semiconductor device structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

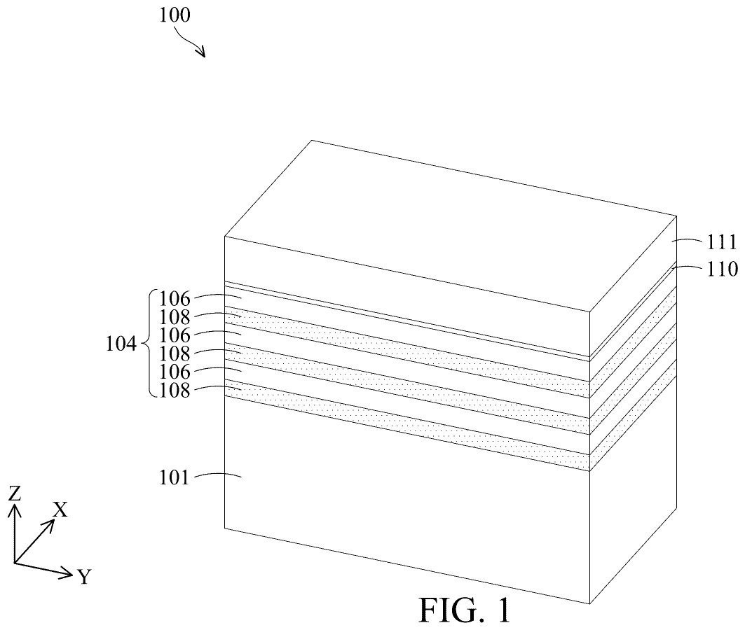

FIGS. 1 to 21 show exemplary processes for manufacturing a semiconductor device structure 100 according to embodiments of the present disclosure. It is understood that additional operations can be provided before, during, and after processes shown by FIGS. 1 to 21, and some of the operations described below can be replaced or eliminated, for additional embodiments of the method. The order of the operations/processes is not limiting and may be interchangeable.

FIGS. 1 to 13 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm, such as from about 3 nm to about 10 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

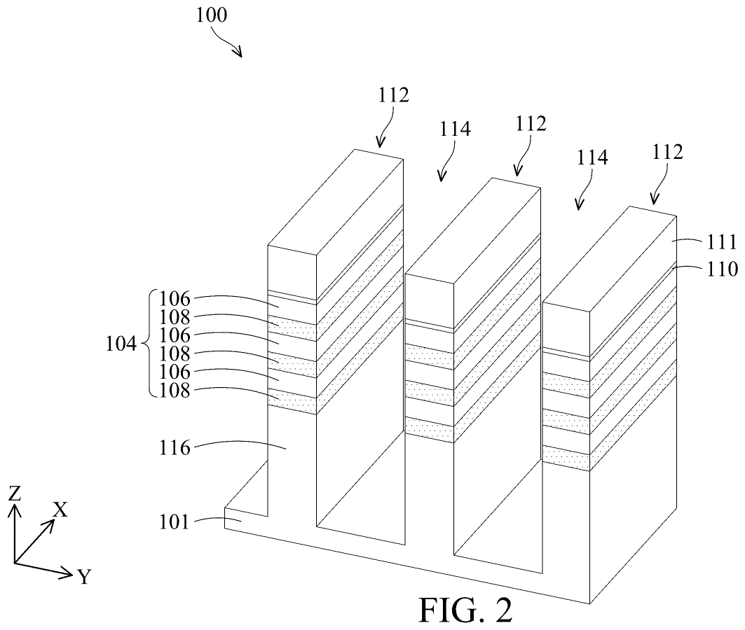

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

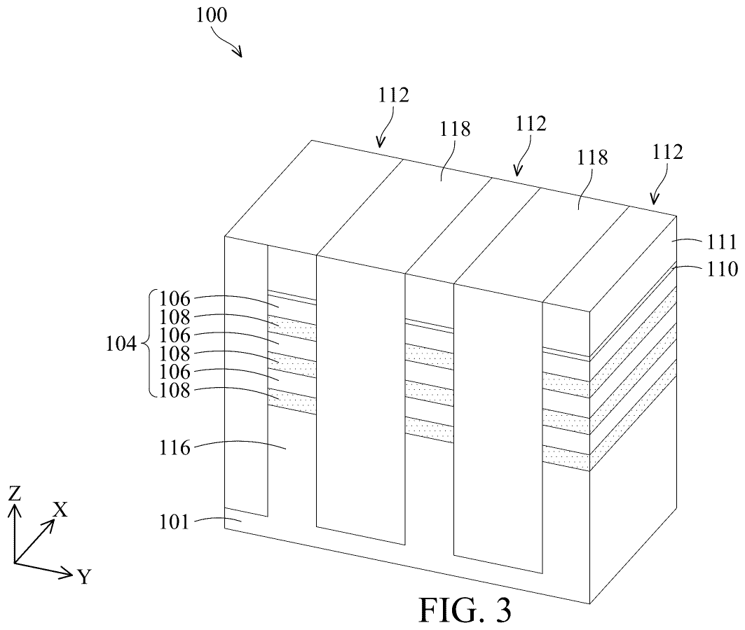

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

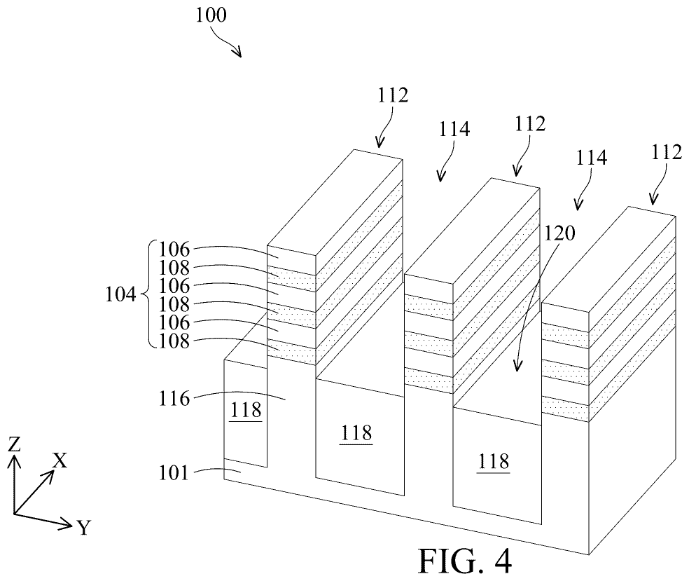

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the STI. In some embodiments, the oxide layer 110 and the nitride layer 111 are also removed during the recessing of the insulating material 118.

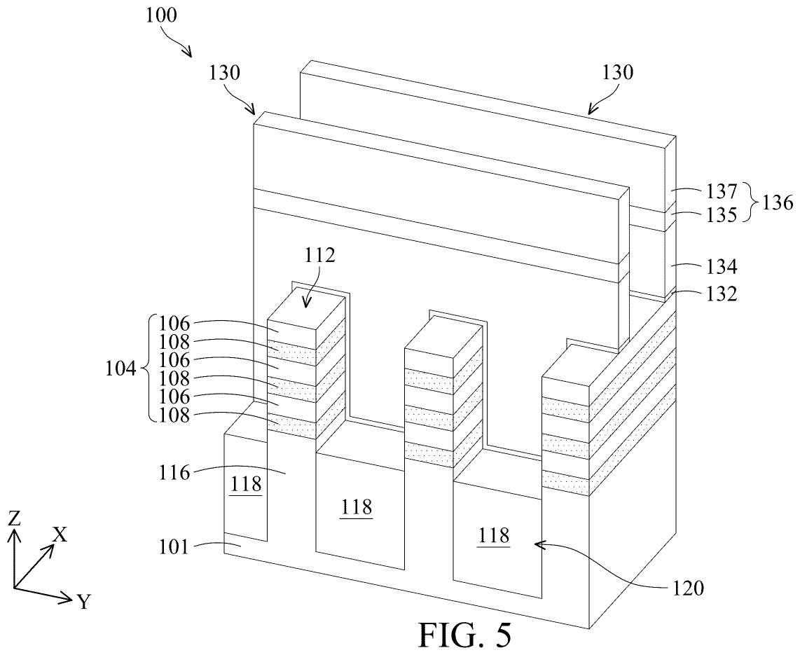

In FIG. 5, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The portions of the fin structures 112 that are covered by the sacrificial gate electrode layer 134 of the sacrificial gate structure 130 serve as channel regions for the semiconductor device structure 100.

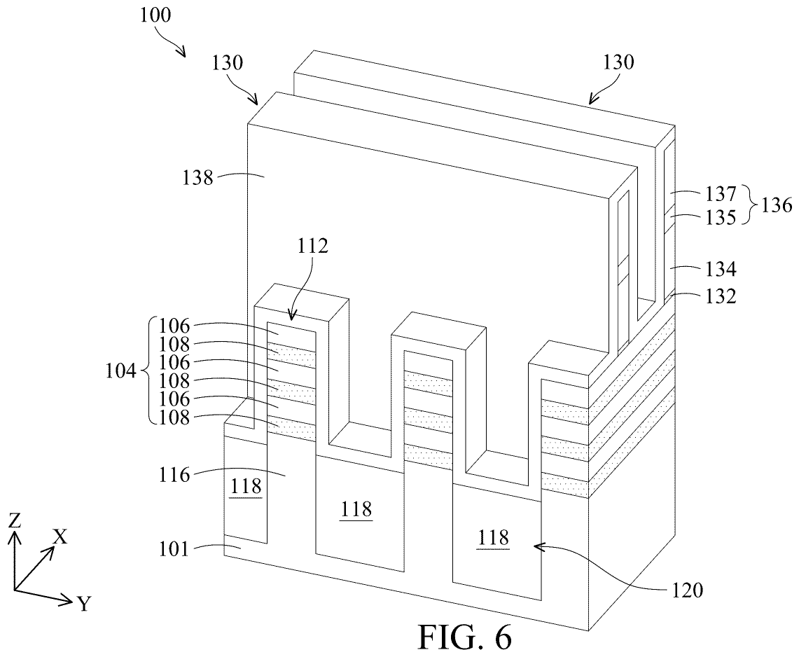

In FIG. 6, a gate spacer layer 138 is formed to cover the sacrificial gate structures 130, the second portions of the fin structures 112, and the second portions of the isolation regions 120. The gate spacer layer 138 may include one or more layers of dielectric material, such as silicon oxide, silicon nitride, silicon carbide, silicon oxynitride, SiCN, silicon oxycarbide, SiOCN, and/or combinations thereof. In some embodiments, the gate spacer layer 138 is formed by a conformal process, such as an atomic layer deposition (ALD) process.

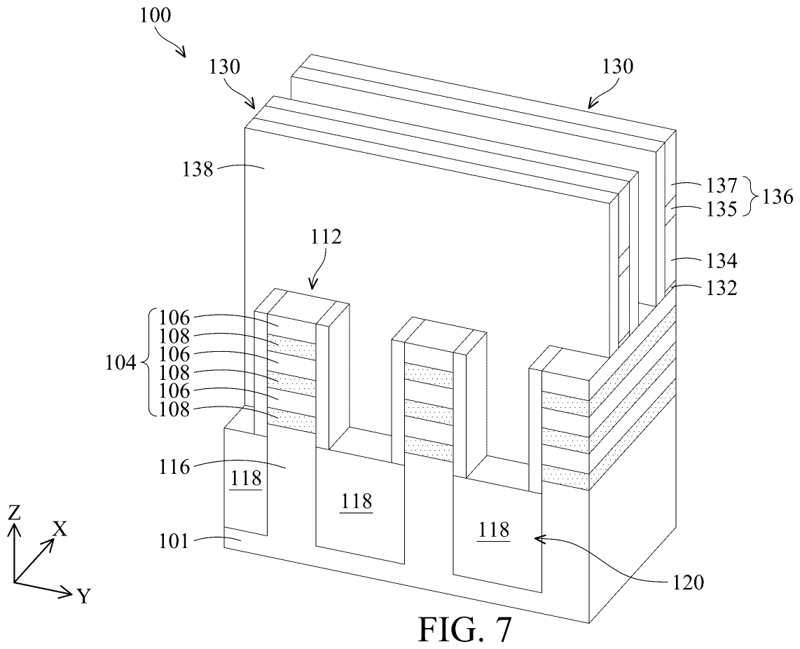

In FIG. 7, an anisotropic etch process is performed to remove horizontal portions of the gate spacer layer 138. The anisotropic etch process may be a selective etch process that does not substantially affect the nitride layer 137, the first semiconductor layer 106, and the isolation region 120. As a result, the second portions of the fin structures 112 are exposed.

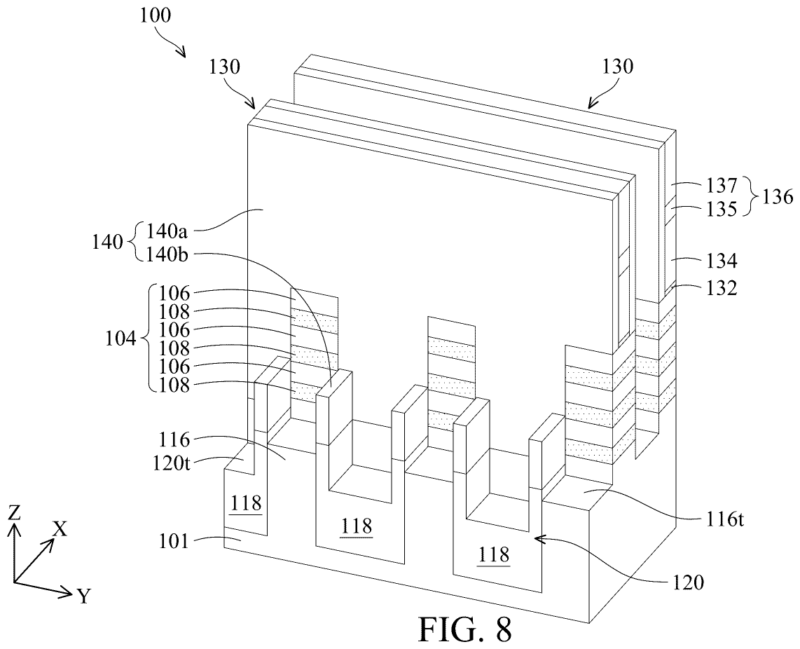

In FIG. 8, one or more etch processes are performed to recess the exposed second portions of the fin structures 112 not covered by the sacrificial gate structures 130 (and the portions of the gate spacer layer 138 formed on sidewalls of the sacrificial gate structures 130) and to remove portions of the gate spacer layer 138. The portions of the gate spacer layer 138 formed on sidewalls of the mask layer 136 may be also recessed. The one or more etch processes may include a dry etch, such as a RIE, NBE, or the like, and/or a wet etch, such as using tetramethyalammonium hydroxide (TMAH), ammonium hydroxide (NH₄OH). The one or more etch processes form gate spacers 140 including a first portion 140a formed on sidewalls of the sacrificial gate electrode layer 134 and second portions 140b formed on the second portions of the isolation regions 120. In some embodiments, the one or more etch processes also remove portions of the second portions of the isolation regions 120, as shown in FIG. 8. As a result, the top surface 120t of the second portion of the isolation region 120 is located at a level substantially below the top surface 116t of the substrate portion 116.

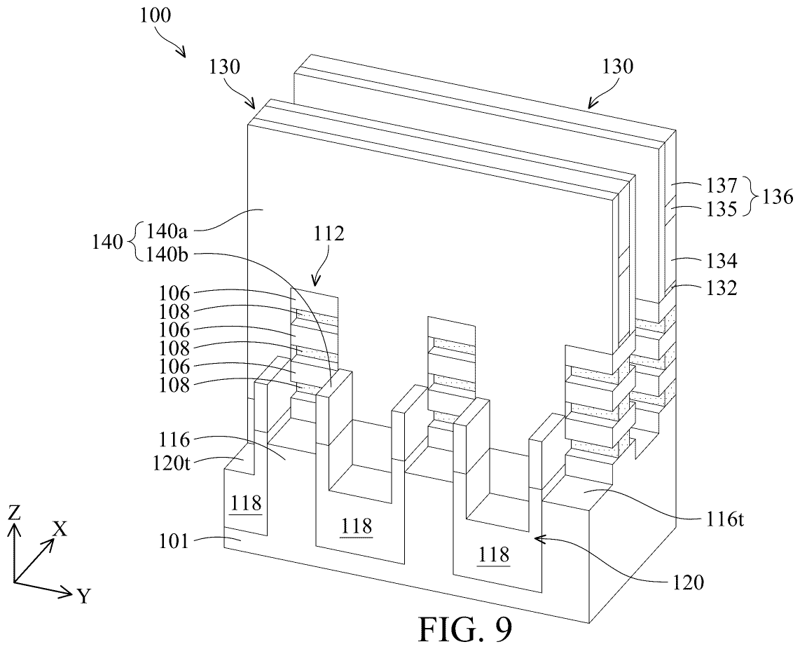

As shown in FIG. 9, edge portions of each second semiconductor layer 108 of the stack of semiconductor layers 104 are removed horizontally along the X direction. The removal of the edge portions of the second semiconductor layers 108 forms cavities. In some embodiments, the edge portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

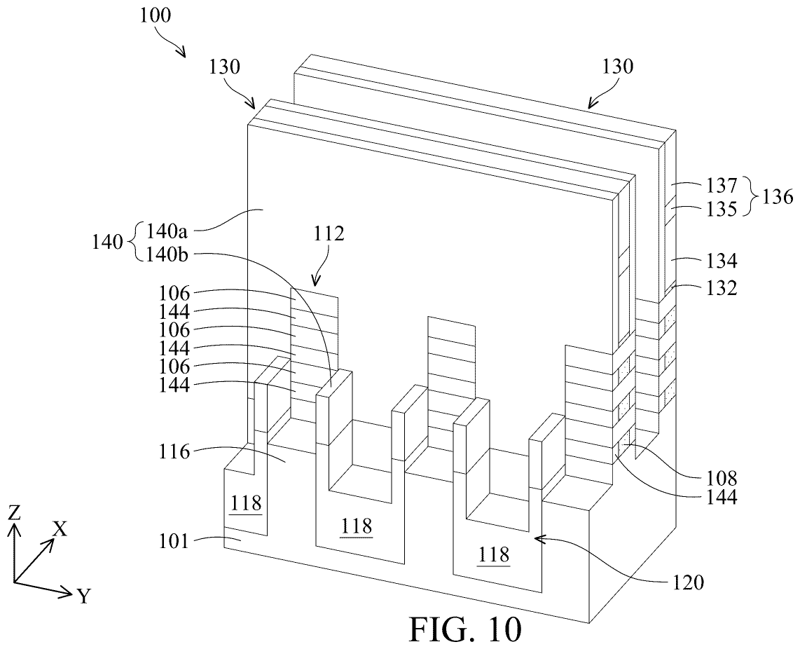

After removing edge portions of each second semiconductor layers 108, a dielectric layer is deposited in the cavities to form dielectric spacers 144, as shown in FIG. 10. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

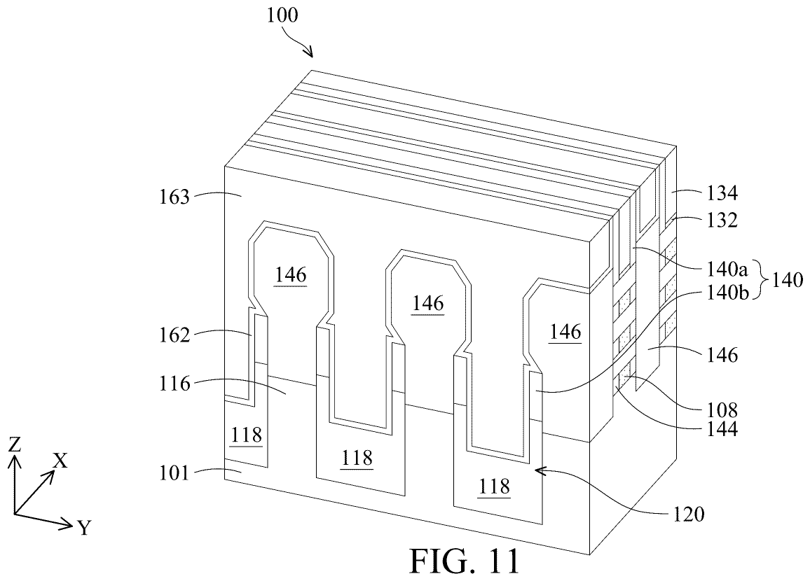

As shown in FIG. 11, source/drain (S/D) regions 146 are formed from the substrate portions 116. In some embodiments, the S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. In some embodiments, the S/D regions 146 are n-type S/D epitaxial features and may be made of one or more layers of Si, SiP, SiC and SiCP for n-channel FETs. In some embodiments, the S/D regions 146 are p-type epitaxial features and may be made of one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. In some embodiments, a thickness of the S/D region 146 along the Z direction is different from a width of the S/D region 146 along the Y direction.

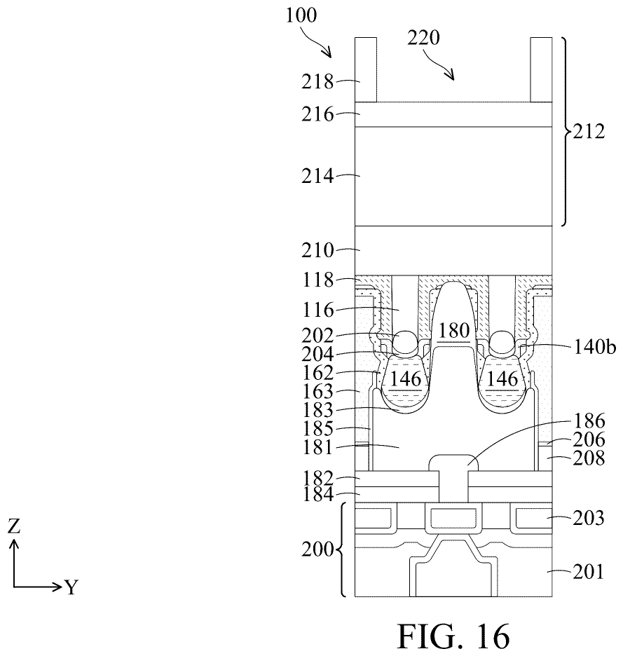

In some embodiments, a semiconductor layer 202 (FIG. 16) is first formed on the substrate portions 116, a dielectric layer 204 (FIG. 16) is formed on the semiconductor layer 202, and the S/D regions 146 are formed from the first semiconductor layers 106. The semiconductor layer 202 may be undoped silicon, and the dielectric layer 204 may be a nitride layer, such as a SiN layer.

After forming the S/D regions 146, a contact etch stop layer (CESL) 162 is conformally formed on the exposed surfaces of the semiconductor device structure 100. The CESL 162 covers the sidewalls of the first portion 140a of the gate spacers 140 and is disposed on the second portion 140b of the gate spacers 140 and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

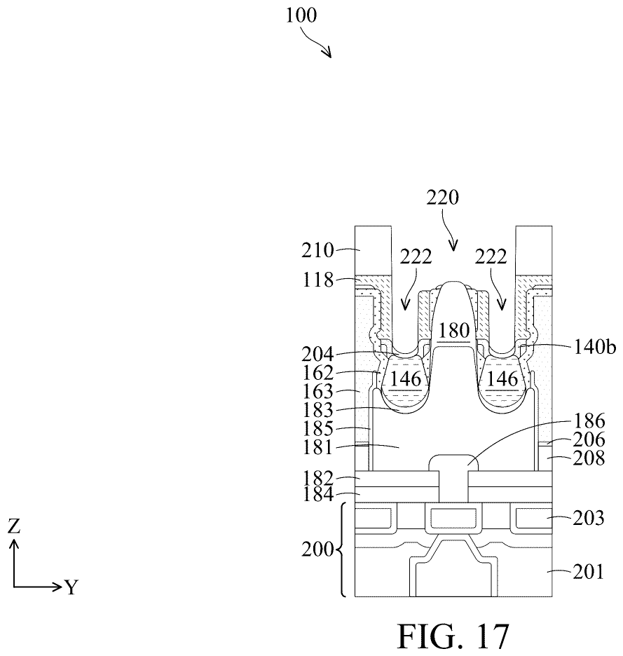

A planarization process is performed to expose the sacrificial gate electrode layer 134, as shown in FIG. 17. The planarization process may be any suitable process, such as a CMP process. The planarization process removes portions of the ILD layer 163 and the CESL 162 disposed on the sacrificial gate structures 130. The planarization process may also remove the mask layer 136.

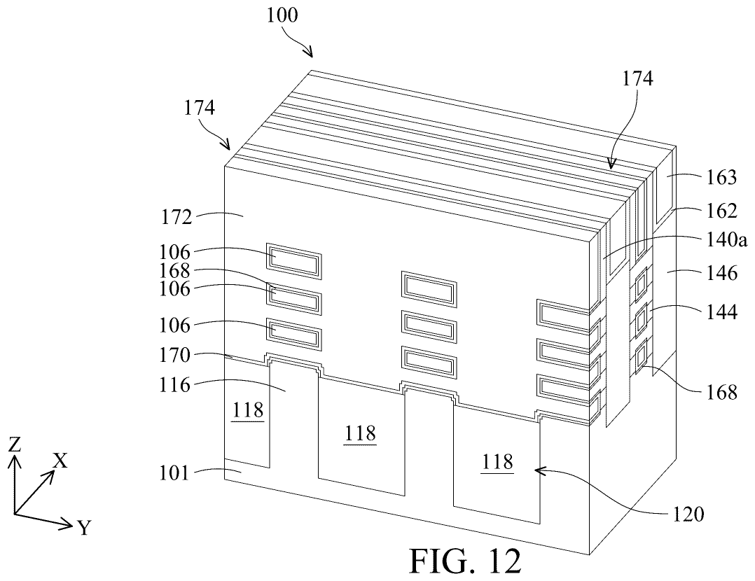

As shown in FIG. 12, the sacrificial gate electrode layer 134, the sacrificial gate dielectric layer 132, and the second semiconductor layers 108 are removed to expose portions of the first semiconductor layers 106, and a gate dielectric layer 170 and a gate electrode layer 172 are formed to surround the exposed portions of the first semiconductor layers 106. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 140, the ILD layer 163, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the spacers 140, the ILD layer 163, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

As shown in FIG. 12, the gate dielectric layer 170 and the gate electrode layer 172 may be collectively referred to as a gate structure 174. In some embodiments, an interfacial layer (IL) 168 is formed between the gate dielectric layer 170 and the exposed surfaces of the first semiconductor layers 106. The IL 168 may include an oxide, such as silicon oxide, and may be formed as a result of a clean process. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate dielectric layer 170 and the gate electrode layer 172 may be also deposited over the ILD layer 163. The gate dielectric layer 170 and the gate electrode layer 172 formed over the ILD layer 163 are then removed by using, for example, CMP, until the top surface of the ILD layer 163 is exposed.

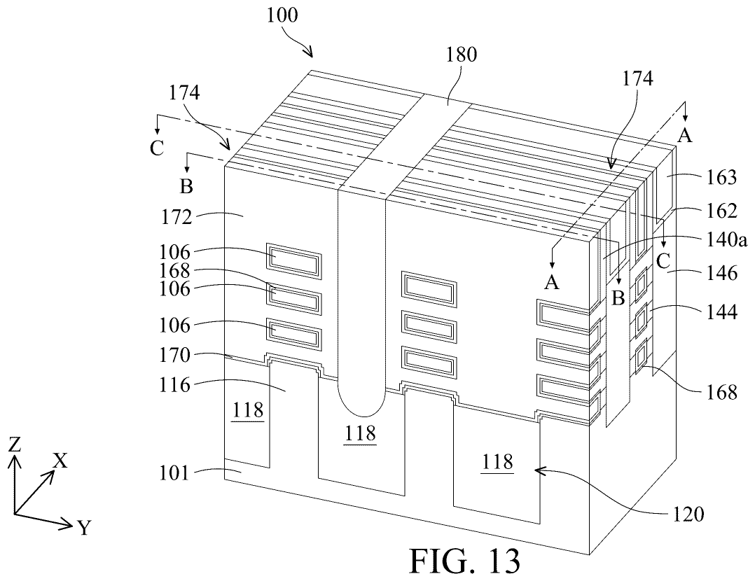

As shown in FIG. 13, a cut metal gate (CMG) process is performed to form a dielectric layer 180 through the gate electrode layer 172. In some embodiments, an opening is formed in the gate electrode layer 172, and the opening may extend through the gate dielectric layer 170 and into the insulating material 118. Then, the dielectric layer 180 is deposited in the opening, and the dielectric layer 180 may extend through the gate electrode layer 172, the gate dielectric layer 170, and into the insulating material 118, as shown in FIG. 13. The dielectric layer 180 electrically separate the gate electrode layer 172 into two portions that can be individually controlled.

Additional process, such as a continuous poly on diffusion edge (CPODE) process, may be performed, and the CPODE process forms isolation between devices.

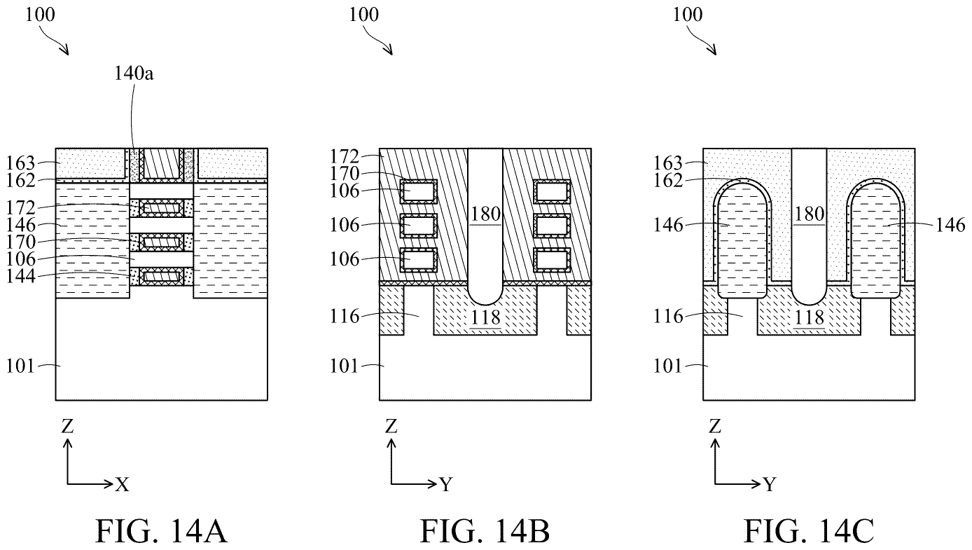

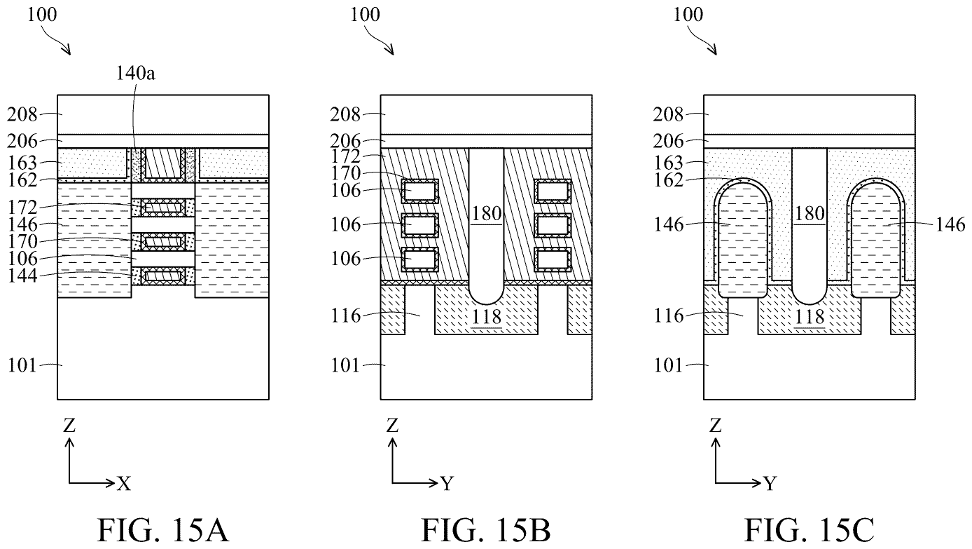

FIGS. 14A and 15A are cross-sectional side views of the semiconductor device structure 100 taken along the line A-A of FIG. 13, in accordance with some embodiments. FIGS. 14B and 15B are cross-sectional side views of the semiconductor device structure 100 taken along the line B-B of FIG. 13, in accordance with some embodiments. FIGS. 14C and 15C are cross-sectional side views of the semiconductor device structure 100 taken along the line C-C of FIG. 13, in accordance with some embodiments. FIGS. 14A, 14B, and 14C illustrate the semiconductor device structure 100 at the same manufacturing stage as the semiconductor device structure 100 shown in FIG. 13. As shown in FIGS. 14B and 14C, in some embodiments, the dielectric layer 180 is also formed between adjacent S/D regions 146.

Next, as shown in FIGS. 15A, 15B, and 15C, another etch stop layer 206 is deposited on the ILD layer 163, and another ILD layer 208 is deposited on the etch stop layer 206. The etch stop layer 206 may include the same material as the CESL 162, and the ILD layer 208 may include the same material as the ILD layer 163. In some embodiments, a thickness of the ILD layer 163 is greater than a thickness of the ILD layer 208, as shown in FIG. 15C.

As shown in FIG. 16, in some embodiments, an opening is formed in the ILD layer 208, the etch stop layer 206, the ILD layer 163, and the CESL 162 to expose the S/D regions 146, and a conductive feature 181 is formed in the opening and is electrically connected to the S/D regions 146 via silicide layers 183. In some embodiments, a portion of the conductive feature 181 extends between the adjacent S/D regions 146, as shown in FIG. 16. In such embodiments, the opening is also formed in a portion of the dielectric layer 180, and the conductive feature 181 extends into the dielectric layer 180. In some embodiments, the conductive feature 181 does not extend between the adjacent S/D regions 146. In such embodiments, one or more etch processes to form the opening do not substantially affect the material of the dielectric layer 180.

The conductive feature 181 provides power or signal to the S/D regions 146 from the frontside of the semiconductor device structure 100. Conductive features (not shown) may be formed in the ILD layer 208 and the etch stop layer 206 to electrically connect with the gate structures 174. The conductive feature 181 may include any suitable electrically conductive material, such as tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. The silicide layers 183 may be formed by depositing one or more metals into the opening, performing an annealing process to cause reaction between the one or more metals and the S/D regions 146 to produce the silicide layers 183, and removing un-reacted portions of the one or more metals, leaving the silicide layers 183 in the opening. The one or more metals may include titanium (Ti), tantalum (Ta), tungsten (W), nickel (Ni), platinum (Pt), ytterbium (Yb), iridium (Jr), erbium (Er), cobalt (Co), or a combination thereof (e.g., an alloy of two or more metals) and may be deposited using CVD, PVD, ALD, or other suitable methods. The silicide layer 183 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. Alternatively, the conductive feature 181 may directly contact the adjacent S/D regions 146.

In some embodiments, a dielectric liner 185 is formed on the sidewall of the opening prior to forming the conductive feature 181. The dielectric liner 185 may include any suitable dielectric material, such as La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, or ZrSi. The dielectric liner 185 may be formed by first forming a conformal layer in the opening followed by an anisotropic etching process to remove horizontal portions of the conformal layer.

Next, an etch stop layer 182 and another ILD layer 184 are formed on the ILD layer 208 and the conductive feature 181, as shown in FIG. 16. The etch stop layer 182 may include the same material as the CESL 162 and may be formed by the same process as the CESL 162. The ILD layer 184 may include the same material as the ILD layer 163 and may be formed by the same process as the ILD layer 163. A conductive feature 186 is formed in the etch stop layer 182 and the ILD layer 184. In some embodiments, the conductive feature 186 extends into the conductive feature 181. The conductive feature 186 may include an electrically conductive material, such as Cu, Co, W, Ru, Ni, Pt, Ti, Ta, or other suitable material.

An interconnect structure 200 is formed over the ILD layer 184, as shown in FIG. 16. The interconnect structure 200 includes a plurality of intermetal dielectric (IMD) layers 201 and conductive features 203, such as conductive lines and vias, formed in the IMD layers 201. The interconnect structure 200 may further include passivation layers, adhesion layers, and/or other layers formed on the frontside of the semiconductor device structure 100. Next, a carrier substrate (not shown) is attached to the semiconductor device structure 100 on the frontside, and the semiconductor device structure 100 is flipped over for backside processing, as shown in FIG. 16. In some embodiments, the substrate 101 is thinned down until the insulating material 118 is shown, as shown in FIG. 16. The thinning process may include a mechanical grinding process and/or a chemical thinning process. A substantial amount of substrate material may be first removed from the substrate 101 during a mechanical grinding process. Afterwards, a chemical thinning process may apply an etching chemical to the backside of the substrate 101 to further thin down the substrate 101.

As shown in FIG. 16, a hardmask layer 210 is deposited over the backside of the semiconductor device structure 100 and a tri-layer resist layer 212 is formed over the hardmask layer 210. The hardmask layer 210 may include an oxide (e.g., SiO₂), a nitride (e.g., SiN), an oxy-nitride (e.g., SiOₓN_{y}), or the like. In further embodiments, the hardmask layer 210 is SiO₂. In yet further embodiments, the hardmask layer 210 is a high-temperature oxide (HTO) (e.g., SiO₂ formed by a high-temperature deposition/growth process). In some embodiments, a process for forming the hardmask layer 210 includes depositing a dielectric material on the backside of the semiconductor device structure 100 by, for example, CVD, PVD, ALD, sputtering, some other deposition process, or a combination thereof.

The tri-layer resist layer 212 includes a bottom layer 214 over the hardmask layer 210, a middle layer 216 over the bottom layer 214, and an upper layer 218 over the middle layer 216. The bottom layer 214 may be a bottom anti-reflective coating (BARC). The bottom layer 214 may include organic materials. The middle layer 216 may be formed from or include an inorganic material, which may be a nitride (such as silicon nitride), an oxynitride (such as silicon oxynitride), an oxide (such as silicon oxide), or the like. The upper layer 218 is a photosensitive material. In some embodiments, the resist layer formed over the hardmask layer 210 may be another type of photoresist, such as a single-layer photoresist, a bi-layer photoresist, or the like. The upper layer 218 is patterned using any suitable photolithography technique to form trench opening 220 therein.

As shown in FIG. 17, the trench opening 220 is extended to the hardmask layer 210 and selectively etches the substate portions 116 to form backside via holes 222. The pattern of the upper layer 218 is transferred to the middle layer 216 using a suitable etching process. Next, a suitable etching process is performed to transfer the pattern of the middle layer 216 to the bottom layer 214, thereby extending the trench opening 220 through the bottom layer 214. Further, the pattern of the bottom layer 214 is transferred to the hardmask layer 210 using a suitable etching process. In an embodiment, the etching process used to etch the bottom layer 214 is continued to etch the hardmask layer 210. During the etching process, the upper layer 218, middle layer 216, and bottom layer 214 may be consumed. In some embodiments, an ashing process may be performed to remove remaining residue of the bottom layer 214. After the patten of the hardmask layer 210 exposes the backside of the semiconductor device structure 100, an etching process that is tuned to be selective to the materials of the substrate portions 116 is performed. In the present embodiment, the etching process also etches the semiconductor layer 202. The dielectric layer 204 may function as an etch stop layer to protect the S/D regions 146 from being etched. In some embodiments, the dielectric layer 180 include the same material as the dielectric layer 204, and the dielectric layer 180 is not substantially affected at this stage of manufacturing. The etching process can be dry etching, wet etching, reactive ion etching, or other suitable etching methods.

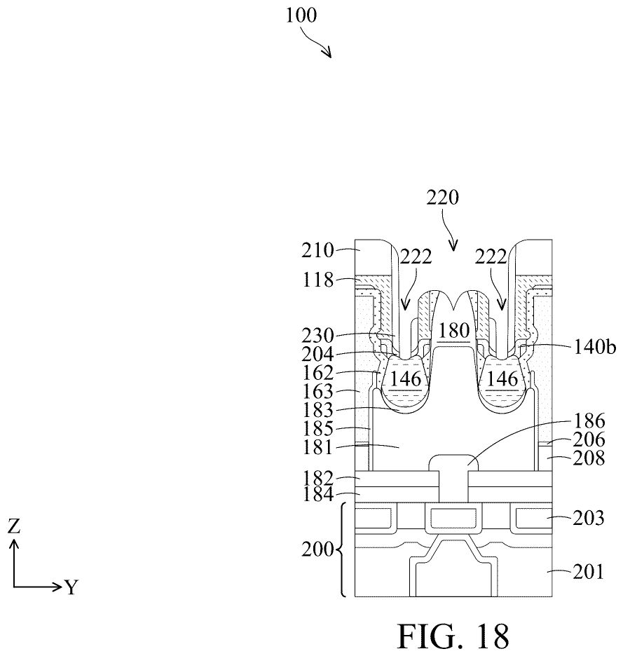

As shown in FIG. 18, a dielectric liner 230 is formed on sidewalls of the trench opening 220 (including backside via holes 222). The dielectric liner 230 further protects the gate structure 174 from metal element diffusion when conductive features are subsequently formed in the trench opening 220. In some embodiments, the dielectric liner 230 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, combinations thereof, or other suitable material(s). The dielectric liner 230 may be first deposited using ALD, CVD, or other suitable methods. Subsequently, an anisotropic etching process is performed to remove the horizontal portions of the dielectric liner 230. In the illustrated embodiment, as a result of the anisotropic etching process, portions of the dielectric liner 230 remain on sidewalls of the insulating material 118. The dielectric liner 230 may also be in contact with the second portion 140b of the gate spacer 140. After the anisotropic etching process, the dielectric layer 204 as an etch stop layer is exposed in the backside via holes 222. Subsequently, an etching process is applied to remove the exposed portion of the dielectric layer 204. The etching process can be dry etching, wet etching, reactive ion etching, or other etching methods. After the etching process, the backside via holes 222 exposes bottom surface of the S/D regions 146 from the backside. A portion of the dielectric layer 204 may remain between the S/D region 146 and the dielectric liner 230.

In some embodiments, the anisotropic etch process to form the dielectric liner 230 and the etching process to remove the exposed portion of the dielectric layer 204 also remove a portion of the CESL 162 and a portion of the dielectric layer 180, as shown in FIG. 18. In some embodiments, the anisotropic etch process to form the dielectric liner 230 and the etching process to remove the exposed portion of the dielectric layer 204 do not substantially affect the dielectric layer 180.

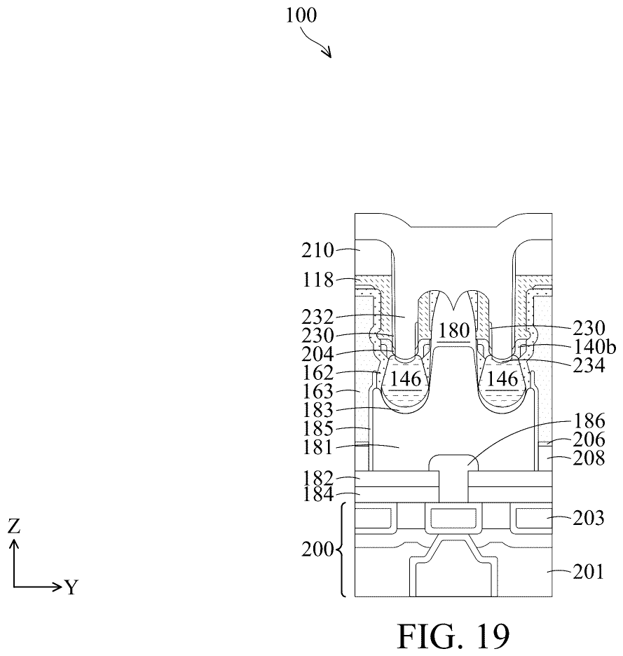

As shown in FIG. 19, a conductive feature 232 is formed in the trench opening 220 and the backside via holes 222. The conductive feature 232 may include the same material as the conductive feature 181 and may be formed by the same process as the conductive feature 181. In some embodiments, a silicide layer 234 is formed between the conductive feature 232 and the S/D region 146. The silicide layer 234 reduces contact resistance between the S/D regions 146 and the conductive feature 232. The silicide layers 234 may include the same material as the silicide layer 183 and may be formed by the same process as the silicide layer 183. Alternatively, the conductive feature 232 may directly contact the two S/D regions 146.

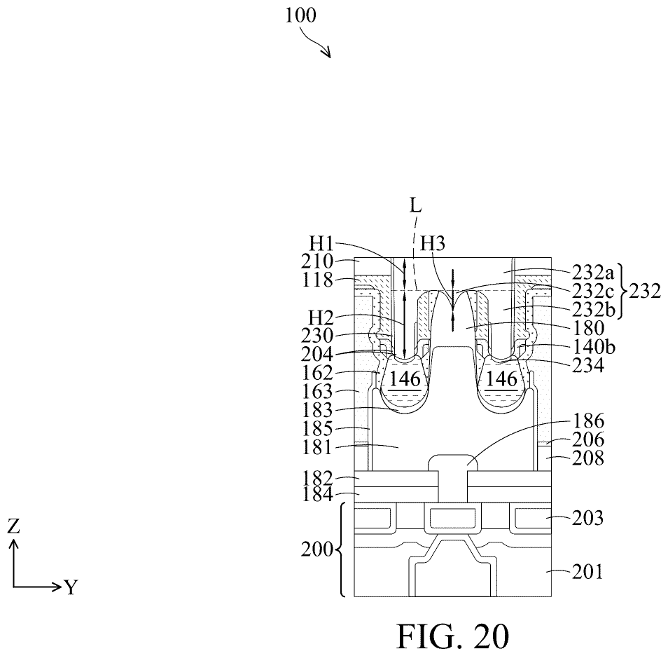

As shown in FIG. 20, a planarization process, such as a CMP process, is performed to remove the portion of the conductive feature 232 formed on the hardmask layer 210. In some embodiments, the top surface of the conductive feature 232 and the top surface of the hardmask layer 210 are substantially coplanar. The conductive feature 232 has a first portion 232a and second portions 232b extending from edges of the first portion 232a, as shown in FIG. 20. The conductive feature 232 may further include a third portion 232c extending from the center of the first portion 232a. The conductive feature 232 is monolithic, and the first, second, and third portions 232a, 232b, 232c are defined by an imaginary line L, as shown in FIG. 20. The imaginary line L may be drawn at a location so the height H1 is constant. The first portion 232a has a height H1, the second portion 232b has a height H2, and the third portion 232c has a height H3. In some embodiments, the height H1 is less than the height H2, and the height H3 is less than the height H1, as shown in FIG. 20. In some embodiments, the height H1 is greater than the height H2. The third portion 232c provides a larger volume of the conductive feature 232. As a result, electrical resistance is reduced.

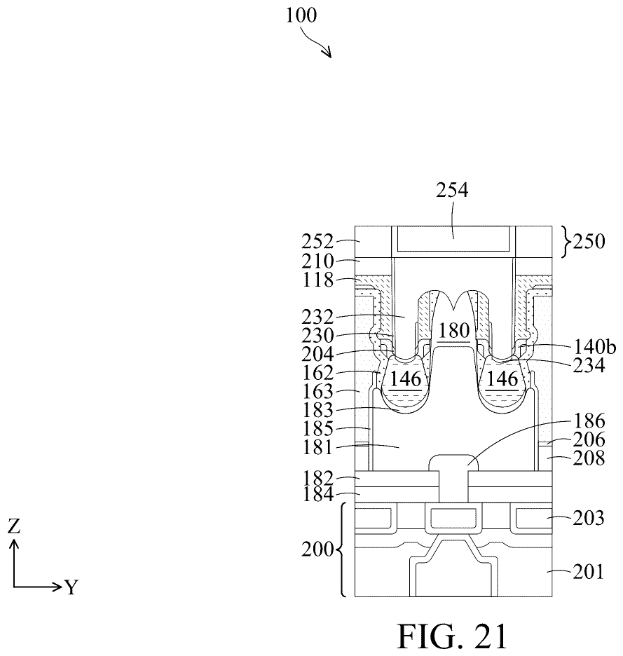

As shown in FIG. 21, backside interconnect structure 250 is formed on the hardmask layer 210 and the conductive feature 232. The backside interconnect structure 250 includes one or more IMD layers 252 and conductive features 254 formed in the IMD layers 252.

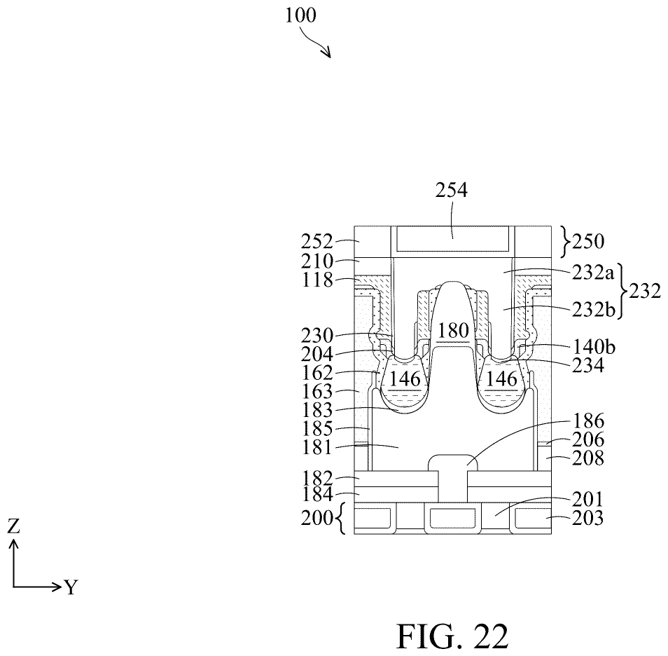

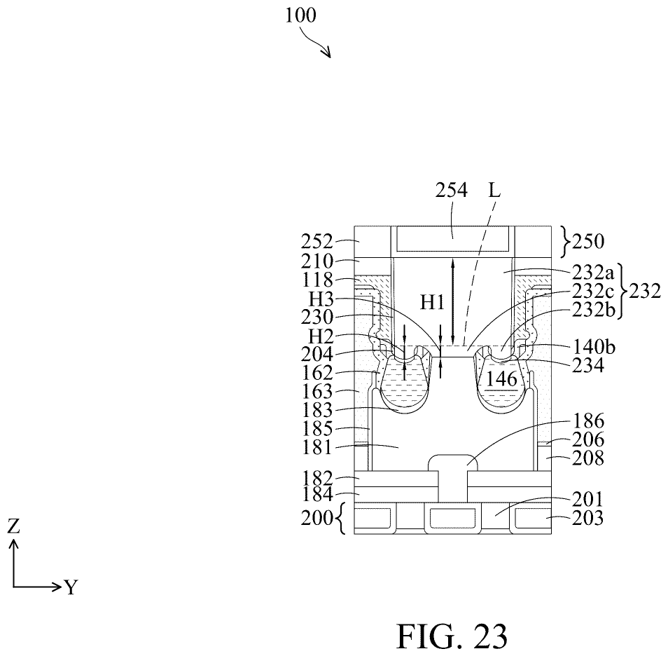

FIGS. 22 and 23 are cross-sectional side views of the semiconductor device structure 100 at one of various manufacturing stages, in accordance with alternative embodiments. As shown in FIG. 22, in some embodiments, the conductive feature 232 does not extend into the dielectric layer 180. Thus, instead of having the third portion 232c (FIG. 21), the conductive feature 232 includes the first portion 232a having a recess in the center, as shown in FIG. 22. Compared to the conductive feature 232 shown in FIG. 21, the conductive feature 232 shown in FIG. 22 has a higher electrical resistance and smaller capacitance due to smaller size.

In some embodiments, the etch processes to form the opening for the conductive feature 232 also removes the dielectric layer 180 to expose the conductive feature 181 located between adjacent S/D regions 146, and the conductive feature 232 are in contact with the conductive feature 181, as shown in FIG. 23. Compared to the conductive features 232 shown in FIGS. 21 and 22, the conductive feature 232 shown in FIG. 23 has the lowest electrical resistance and largest capacitance due to larger size. In some embodiments, as shown in FIG. 23, the height H1 of the first portion 232a of the conductive feature 232 is greater than the height H2 of the second portion 232b of the conductive feature 232. The height H2 of the second portion 232b may be the same as the height H3 of the third portion 232c, as shown in FIG. 23. In some embodiments, the width of the second portion 232 b along the Y direction is smaller than the width of the third portion 232c, as shown in FIG. 23.

In some embodiments, the semiconductor device structure 100 includes memory devices, such as static random access memory (SRAM). For SRAM devices, the SRAM cell current is limited by the electrical resistance of the conductive features connected to a reference voltage Vss and a supply voltage Vdd. In some embodiments, the conductive feature 232 is the conductive feature connected to the Vss or the Vdd. Thus, by increasing the size of the conductive feature 232 to across two S/D regions 146, the resistance is reduced. Furthermore, by placing the conductive feature 232 on the backside of the semiconductor device structure 100, the signal or power routing is less crowded. Furthermore, the size of the conductive feature 232 may be greater than the size of the conductive feature 181, because the backside signal or power routing is less crowded than the frontside signal or power routing.

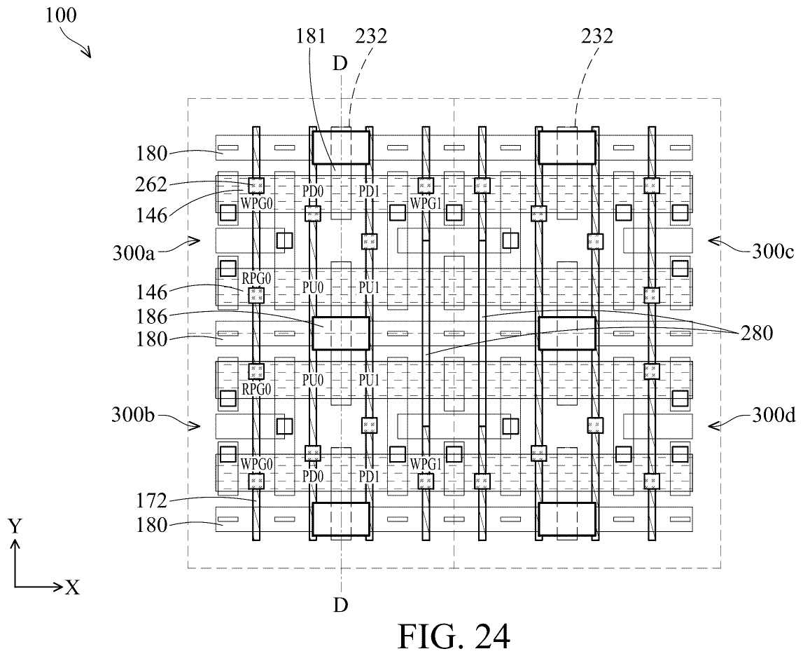

FIG. 24 is a top view of the semiconductor device structure 100, in accordance with some embodiments. As shown in FIG. 24, the semiconductor device structure 100 includes a plurality of memory cells 300a, 300b, 300c, 300d. In some embodiments, each memory cell 300a, 300b, 300c, 300d includes seven transistors (sometimes referred to as a “7T SRAM”). For example, each memory cell 300a, 300b, 300c, 300d includes a pull-up 0 transistor (PU0), a pull-up 1 transistor (PU1), a pull-down 0 transistor (PD0), a pull-down 1 transistor (PD1), a write pass gate 0 transistor (WPG0), a write pass gate 1 transistor (WPG1), and a read pass gate 0 transistor (RPG0). In some embodiments, the transistors PU0, PU1, and RPG0 are each implemented as a p-type metal-oxide-semiconductor field-effect-transistor (MOSFET), and the transistors PD0, PD1, WPG0, and WPG1 are each implemented as an n-type MOSFET. However, it should be understood that these transistors can each be configured otherwise, while remaining within the scope of the present disclosure. Furthermore, the memory cells may be any suitable memory cells, such as 6T SRAM or 8T SRAM.

In some embodiments, as shown in FIG. 24, a portion of one or more gate electrode layer 172 is replaced with a dielectric layer 280 by the CPODE process to electrically isolate the four memory cells 300a, 300b, 300c, and 300d. In some embodiments, as shown in FIG. 24, a width of the conductive feature 181 along the X direction is substantially the same as a width of the conductive feature 232 (shown in dotted lines) along the X direction.

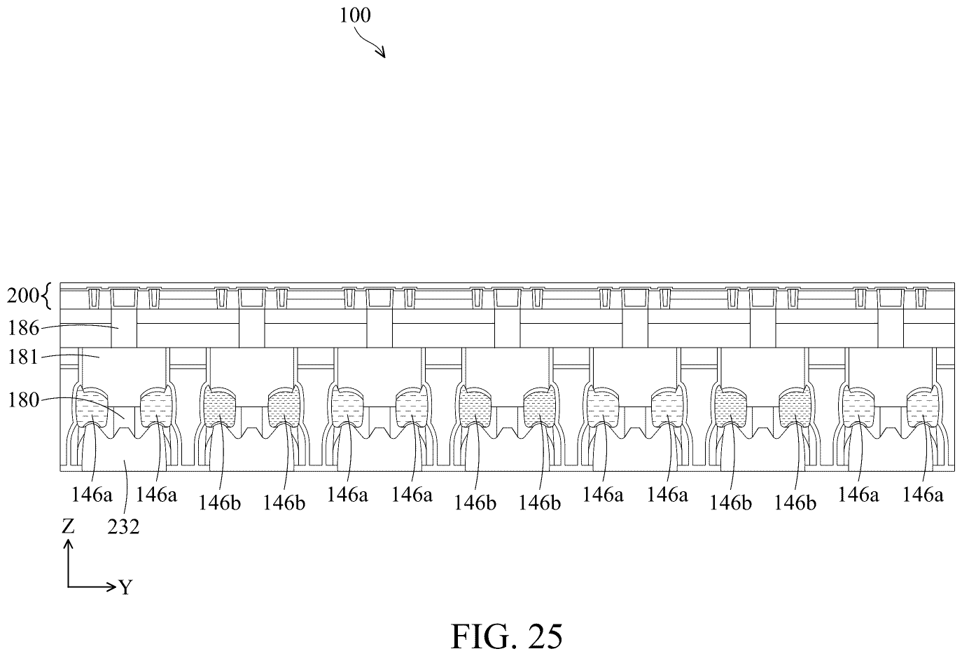

FIG. 25 is a cross-sectional side view of the semiconductor device structure 100 taken along the line D-D of FIG. 24, in accordance with some embodiments. As shown in FIG. 25, the semiconductor device structure 100 includes a plurality of conductive features 232 and a plurality of conductive features 181 disposed along the Y direction. The conductive features 181 are disposed over corresponding conductive features 232. In some embodiments, two S/D regions 146a (or S/D regions 146b) are disposed between a conductive feature 181 and a corresponding conductive feature 232, as shown in FIG. 25. In some embodiments, the dielectric layer 180 is disposed between the two S/D regions 146a, as shown in FIGS. 21 and 22. In some embodiments, the conductive features 181, 232 are disposed between the two S/D regions 146a, as shown in FIG. 23. In some embodiments, as shown in FIG. 25, the conductive feature 186 is disposed over the dielectric layer 180. In some embodiments, the S/D regions 146a are of a first conductivity type, such as n-type or p-type, and the S/D regions 146b are of a second conductivity type opposite the first conductivity type. In some embodiments, the S/D regions 146a are n-type S/D regions, and the S/D regions 146b are p-type S/D regions. In some embodiments, the S/D regions 146a are p-type S/D regions, and the S/D regions 146b are n-type S/D regions.

In some embodiments, the corresponding conductive features 181, 232 are connected to the Vss, and the adjacent corresponding conductive features 181, 232 are connected to the Vdd. In some embodiments, the n-type S/D regions 146a are connected to the Vss, and the p-type S/D regions 146b are connected to the Vdd. By electrically connecting the Vss or Vdd to two conductive features 181, 232 having large dimensions (each is connected to two S/D regions 146a or 146b), electrical resistance, such as contact resistance, interface resistance, and/or plug resistance of the conductive features 181, 232 are reduced, and cell current may be increased.

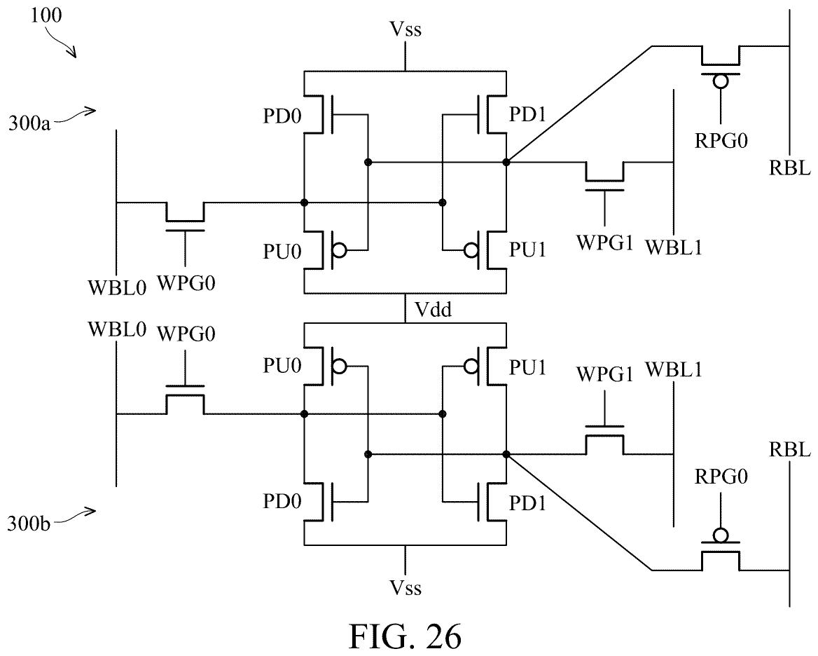

FIG. 26 is a circuit diagram of two 7T SRAM cells 300a, 300b, in accordance with some embodiments. As shown in FIG. 26, each 7T SRAM cell 300a, 300b is connected to two write bit lines WBL and one read bit line RBL. In some embodiments, the Vdd for the 7T SRAM cells 300a, 300b is connected to a single conductive feature 232 (and a single conductive feature 181 in some embodiments). Referring back to FIG. 24, the conductive feature 232 disposed in both cells 300a, 300b is connected to the Vdd. In some embodiments, as shown in FIG. 24, the conductive feature 232 electrically connected to the transistors PU0, PU1 of the cell 300a is also electrically connected to the transistors PU0, PU1 of the adjacent cell 300b. In some embodiments, the conductive feature 181 electrically connected to the transistors PU0, PU1 of the cell 300a is also electrically connected to the transistors PU0, PU1 of the adjacent cell 300b. Similarly, in some embodiments, the conductive feature 232 electrically connected to the transistors PD0, PD1 of the cell 300a is also electrically connected to the transistors PD0, PD1 of the adjacent cell (not shown), and the conductive feature 232 is electrically connected to the Vss. In some embodiments, the conductive feature 181 electrically connected to the transistors PD0, PD1 of the cell 300a is also electrically connected to the transistors PD0, PD1 of the adjacent cell (not shown), and the conductive feature 181 is electrically connected to the Vss.

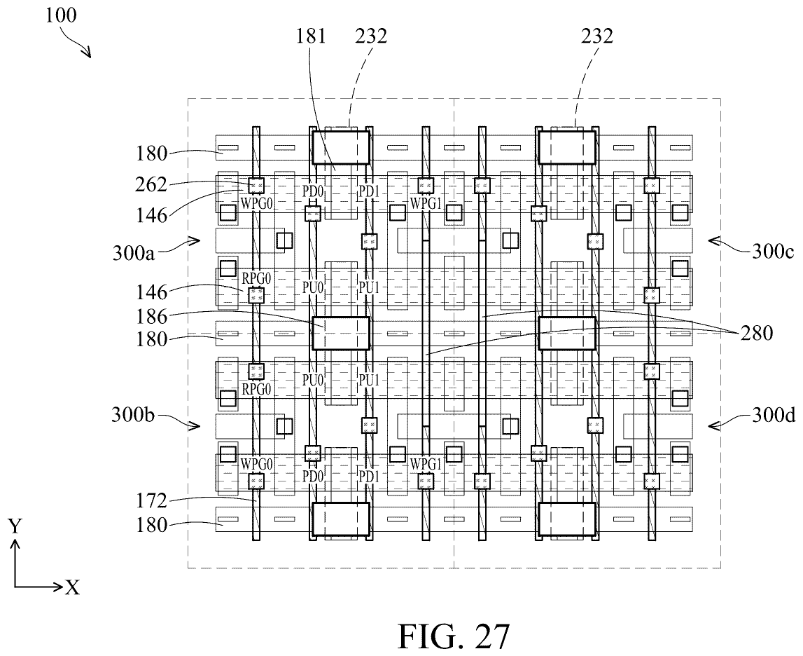

FIG. 27 is a top view of the semiconductor device structure 100, in accordance with alternative embodiments. In some embodiments, as shown in FIG. 27, the conductive feature 181 is formed on the frontside of the semiconductor device structure 100, and the conductive feature 232 (shown in dotted lines) is formed on the backside of the semiconductor device structure 100. Because the backside of the semiconductor device structure 100 is less crowded with the conductive features, the dimensions of the conductive feature 232 may be greater than the dimensions of the conductive feature 181. In some embodiments, the width of the conductive feature 232 along the X direction is greater than the width of the conductive feature 181 along the X direction. With a larger width, the electrical resistance of the conductive feature 232 is further reduced.

In some embodiments, the conductive feature 232 has a length along the Y direction that is equal to two times the length of the fin structure 112 (FIG. 2) along the Y direction plus the distance between the two adjacent fin structures 112. In some embodiments, a ratio of the length of the conductive feature 232 to the length of the fin structure 112 is between about 2.5 and about 7.

Embodiments of the present disclosure provide a semiconductor device structure 100 having a conductive feature 181 located on the frontside of the semiconductor device structure and a conductive feature 232 located on the backside of the semiconductor device structure 100. In some embodiments, the conductive features 181, 232 are electrically connected to two S/D regions 146, and the conductive features 181, 232 may be electrically connected to a Vdd or Vss for two adjacent memory cells. Some embodiments may achieve advantages. For example, by having the conductive features 181, 232 electrically connected to two S/D regions 146, the electrical resistance is reduced.

An embodiment is a semiconductor device structure. The structure includes a first source/drain region, and a thickness of the first source/drain region is different from a width of the first source/drain region in a cross-sectional view. The structure further includes a second source/drain region disposed adjacent the first source/drain region, a contact etch stop layer disposed over the first source/drain region, a first interlayer dielectric (ILD) layer disposed over the contact etch stop layer, an etch stop layer disposed over a top surface of the contact etch stop layer and a top surface of the first ILD layer, and a second ILD layer disposed over the etch stop layer. A thickness of the first ILD layer is greater than a thickness of the second ILD layer. The structure further includes a first conductive feature disposed below the first and second source/drain regions, and the first conductive feature is electrically connected to the first and second source/drain regions. The structure further includes a second conductive feature disposed above the first and second source/drain regions, the second conductive feature is electrically connected to the first and second source/drain regions, and the first and second conductive features are in contact with each other.

Another embodiment is a semiconductor device structure including at least two memory cells. The structure includes a first source/drain region, and a thickness of the first source/drain region is different from a width of the first source/drain region in a cross-sectional view. The structure further includes a second source/drain region disposed adjacent the first source/drain region, a contact etch stop layer disposed over the first source/drain region, a first interlayer dielectric (ILD) layer disposed over the contact etch stop layer, an etch stop layer disposed over a top surface of the contact etch stop layer and a top surface of the first ILD layer, and a second ILD layer disposed over the etch stop layer. A thickness of the first ILD layer is greater than a thickness of the second ILD layer. The structure further includes a first conductive feature disposed below the first and second source/drain regions, the first conductive feature comprises a first portion and second portions extending from edges of the first portion, and the first conductive feature is electrically connected to a reference voltage or a supply voltage for the two memory cells.

A further embodiment is a method. The method includes forming a first source/drain region, and a thickness of the first source/drain region is different from a width of the first source/drain region in a cross-sectional view. The method further includes forming a second source/drain region adjacent the first source/drain region, depositing a contact etch stop layer over the first and second source/drain regions, depositing a first interlayer dielectric (ILD) layer over the contact etch stop layer, depositing an etch stop layer over the first ILD layer and the contact etch stop layer, and depositing a second ILD layer over the etch stop layer. A thickness of the first ILD layer is greater than a thickness of the second ILD layer. The method further includes forming a first conductive feature over the first and second source/drain regions, and a portion of the first conductive feature extends to a location between the first and second source/drain regions. The method further includes flipping over the semiconductor device structure, forming an opening to expose the first and second source/drain regions and the portion of the first conductive feature, and forming a second conductive feature in the opening. The second conductive feature is in contact with the portion of the first conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first source/drain region, wherein a thickness of the first source/drain region is different from a width of the first source/drain region in a cross-sectional view;
a second source/drain region disposed adjacent the first source/drain region;
a contact etch stop layer disposed over the first source/drain region;
a first interlayer dielectric (ILD) layer disposed over the contact etch stop layer;
an etch stop layer disposed over a top surface of the contact etch stop layer and a top surface of the first ILD layer;
a second ILD layer disposed over the etch stop layer, wherein a thickness of the first ILD layer is greater than a thickness of the second ILD layer;
a first conductive feature disposed below the first and second source/drain regions, wherein the first conductive feature is electrically connected to the first and second source/drain regions; and
a second conductive feature disposed above the first and second source/drain regions, wherein the second conductive feature is electrically connected to the first and second source/drain regions, and the first and second conductive features are in contact with each other.

2. The semiconductor device structure of claim 1, wherein a width of the first conductive feature and a width of the second conductive feature are the same.

3. The semiconductor device structure of claim 1, wherein a width of the first conductive feature is greater than a width of the second conductive feature.

4. The semiconductor device structure of claim 1, wherein a portion of the second conductive feature extends to a location between the first and second source/drain regions.

5. The semiconductor device structure of claim 4, wherein the first conductive feature comprises a first portion, second portions extending from edges of the first portion, and a third portion extending from a center of the first portion.

6. The semiconductor device structure of claim 5, wherein the third portion of the first conductive feature is in contact with the portion of the second conductive feature.

7. The semiconductor device structure of claim 1, wherein the second conductive feature is disposed through the second ILD layer, the etch stop layer, the contact etch stop layer, and into the first ILD layer.

8. The semiconductor device structure of claim 7, further comprising a third ILD layer disposed over the second ILD layer and the second conductive feature.

9. The semiconductor device structure of claim 8, further comprising a third conductive feature disposed over the second conductive feature, wherein the third conductive feature is disposed through the third ILD layer.

10. A semiconductor device structure including at least two memory cells, comprising:
a first source/drain region, wherein a thickness of the first source/drain region is different from a width of the first source/drain region in a cross-sectional view;
a second source/drain region disposed adjacent the first source/drain region;
a contact etch stop layer disposed over the first source/drain region;
a first interlayer dielectric (ILD) layer disposed over the contact etch stop layer;
an etch stop layer disposed over a top surface of the contact etch stop layer and a top surface of the first ILD layer;
a second ILD layer disposed over the etch stop layer, wherein a thickness of the first ILD layer is greater than a thickness of the second ILD layer; and
a first conductive feature disposed below the first and second source/drain regions, wherein the first conductive feature comprises a first portion and second portions extending from edges of the first portion, and the first conductive feature is electrically connected to a reference voltage or a supply voltage for the two memory cells.

11. The semiconductor device structure of claim 10, wherein a recess is formed in a center of the first portion of the first conductive feature.

12. The semiconductor device structure of claim 10, wherein the first conductive feature further comprises a third portion extending from a center of the first portion.

13. The semiconductor device structure of claim 12, further comprising a second conductive feature disposed over the first and second source/drain regions.

14. The semiconductor device structure of claim 13, wherein a portion of the second conductive feature extends to a location between the first and second source/drain regions.

15. The semiconductor device structure of claim 14, further comprising a dielectric layer disposed between the third portion of the first conductive feature and the portion of the second conductive feature.

16. The semiconductor device structure of claim 14, wherein the third portion of the first conductive feature is in contact with the portion of the second conductive feature.

17. A method for forming a semiconductor device structure, comprising:
forming a first source/drain region, wherein a thickness of the first source/drain region is different from a width of the first source/drain region in a cross-sectional view;
forming a second source/drain region adjacent the first source/drain region;
depositing a contact etch stop layer over the first and second source/drain regions;
depositing a first interlayer dielectric (ILD) layer over the contact etch stop layer;
depositing an etch stop layer over the first ILD layer and the contact etch stop layer;
depositing a second ILD layer over the etch stop layer, wherein a thickness of the first ILD layer is greater than a thickness of the second ILD layer;
forming a first conductive feature over the first and second source/drain regions, wherein a portion of the first conductive feature extends to a location between the first and second source/drain regions;
flipping over the semiconductor device structure;
forming an opening to expose the first and second source/drain regions and the portion of the first conductive feature; and
forming a second conductive feature in the opening, wherein the second conductive feature is in contact with the portion of the first conductive feature.

18. The method of claim 17, wherein the forming of the second conductive feature comprises:
thinning a substrate to expose an insulating material;
depositing a hardmask layer over the insulating material; and
forming the opening in the hardmask layer and the insulating material.

19. The method of claim 18, wherein the forming of the opening comprises removing a first substrate portion disposed over the first source/drain region and removing a second substrate portion disposed over the second source/drain region.

20. The method of claim 19, wherein the forming of the opening further comprises removing a dielectric layer disposed between the first and second source/drain regions.
